(19) United States
(12) Patent Application Publication
(10) Pub. No.: US 2026/0310849 A1
(43) Pub. Date: Oct. 8, 2026

(54) Method and Device for Optimizing the Robustness of a Digital Twin

(71) Applicant: Siemens Aktiengesellschaft, Muenchen (DE)

(72) Inventors: Christian NEUGEBAUER, Erlangen (DE); Erich GÜNTHER, Erlangen (DE); Sven TAUCHMANN, Chemnitz (DE); Guido SEEGER, Erlangen (DE)

(21) Appl. No.: 19/483,372

(22) PCT Filed: Apr. 3, 2024
(86) PCT No.: PCT/EP2024/058986

§ 371 Date: Nov. 11, 2025

(30) Foreign Application Priority Data
May 12, 2023 (EP) 23173139.9

(51) Int. Cl. G06F 30/20; G05B 17/02

(52) U.S. Cl. CPC G06F 30/20; G05B 17/02

(57) ABSTRACT

Method for optimizing robustness of a system twin that includes a behavior model describing an undisrupted behavior of the system and an expected behavior of the system under influence of at least one predefined disruption, is executed at least twice to obtain simulation data, the overall model is used in an undisrupted state when initially executed and a disruption of the system is also simulated when the overall model is executed for the second time to simulate behavior of the overall system under influence of the disruption acting on the system, simulation data are analyzed to determine an expected effect of the disruption on the overall system from a comparison of data determined when the overall model is initially executed with data determined when the overall model is executed a second time, and at least one action is determined based on the expected effect and communicated to a user.

### CROSS-REFERENCE TO RELATED APPLICATIONS

This is a U.S. national stage of application No. PCT/EP2024/058986 filed 3 Apr. 2024. Priority is claimed on European Application No. 23173139.9 filed 12 May 2023, the content of which is incorporated herein by reference in its entirety.

### BACKGROUND OF THE INVENTION

### 1. Field of the Invention

The present disclosure relates to a computer-assisted method, a facility and a computer program product, in which the robustness of an existing digital twin of a drive system is optimized, and use of such a digital twin for designing a drive system.

### 2. Description of the Related Art

In the context of the design phase and also during operation of a system, there exists the issue of examination of the robustness of this system and the object contained therein. The aim of such an examination is to estimate the risk and the associated costs.

Conventional project engineering of a complex system is usually insufficiently defined with regard to robustness and must be secured in a separate process.

### SUMMARY OF THE INVENTION

In view of the foregoing, it is an object of the present invention to provide a computer-assisted method, in which the robustness of a digital twin of a system (a system twin) is optimized and thus becomes more resilient, in particular more resistant or robust. The system twin comprises a behavior model that describes both an undisrupted behavior and a behavior of the system that is to be expected under the influence of at least one predefined disruption. The at least one disruption preferably occurs with a certain probability in the real production cycle and can be simulated, for example, by injecting a disruptive variable, a disruptive function in the system twin, deactivating a component in the system twin because it fails and malfunctions in the real production cycle, etc.

In the method, a model of an environment (an environment model) is provided. The system is configured to interact with the environment such that the environment supplies at least one input signal (preferably all input signals) to the system and receives at least one output signal (preferably all input signals) from the system, where the system together with the environment form an overall system. The system twin and the environment model are linked (for example, in a simulation tool) to form an overall model, e.g., a model of the overall system. The overall model is executed at least twice to obtain simulation data, where, during a first execution, the overall model is used in an undisrupted state and at least one disruption (disruptive behavior/response of the real system, behavior to an internal and/or external disruption) of the system is co-simulated during a second execution of the overall model to simulate the behavior of the overall system under the influence of the disruption acting on the system. The simulation data is analyzed to ascertain an expected effect of the at least one disruption on the overall system from a comparison of data ascertained during the first execution of the overall model with data ascertained during the second execution of the overall model. Subsequently, depending on the expected effect, at least one action is ascertained and communicated to a user.

In the context of the present disclosure, simulation is taken to mean the execution of a model in a specific configuration and parameterization. One or more simulation(s) with the same model, but with different configurations and/or parameterizations, form(s) a simulation set.

In summary, a ruggedizing method for a digital twin is disclosed, in which the resilience, in particular the robustness of the digital twin with regard to disruptions known from the real production cycle and occurring in the production cycle with a certain frequency, is increased.

In one embodiment, when ascertaining the at least one action, a situation to be expected due to the expected effect of the at least one disruption on the overall system is determined and an evaluation of the situation is performed. A risk-based assessment of the situation in the overall model is preferably performed to decrease the number of relevant faults scenarios based on the ascertained risk to reduce the calculation time. For example, the danger of the resulting overall situation can be used for evaluation.

In one embodiment, a third simulation sequence can be provided, via which the expected effect is quantified.

In another embodiment, the at least one action is evaluated with regard to predefinable parameters. It may be expedient to communicate the result of this evaluation to the user. The parameters can be cost, effort, and/or risks from an omission of the action.

In a further embodiment, two or more disruptions of the system are co-simulated to simulate the behavior of the overall system under the influence of the two or more disruptions acting on the system and to obtain simulation data relating to a plurality of disruptive scenarios.

It can be expedient if the expected effect is ascertained for each disruptive scenario and at least one action for at least one of the expected effect(s) is ascertained and communicated to the user. An action can thus affect a plurality of disruptive scenarios at the same time.

In another embodiment, the at least one action is validated on the overall model, for example, the action is implemented in the overall model and the overall model is simulated at least twice—without and with disruption(s), with it being understood that the disruption(s) is (are) the same as was (were) simulated when determining the at least one action. The expected effect ascertained in this case can preferably be evaluated, for example, evaluated in a risk-based manner. Also, a ranking of the actions can be performed in accordance with various parameters, such as costs, effort, and/or efficiency.

Each disruption or each disruptive scenario can be a disruption of the three following types of disruption or, in the case of a disruption scenario, can include a combination of the disruptions of these types of disturbance or disruption:
disruption on an input or input signal (also results from a disruption of the environment model, also noise);
disruption as its own “non-functional” input (for example, radiation, temperature) ;
disruption as its own logical input (one component malfunctions).

In another embodiment, the expected effect comprises one or more fault(s) within the overall system, i.e., that the disruption(s) result in one or more fault(s). Fault scenarios can be spoken of in this case.

In one embodiment, the action comprises changing the behavior model of the system twin such that the expected effect is lessened. Changing the behavior model can comprise one or more remedial measure(s) for lessening the expected disruptive effect or disruptive influence.

Preferably, the lessening of the expected effect can be effected by an at least partial compensation or by an at least partial offsetting of the influence of the disruption(s) or an elimination of the one or more fault(s).

One of the following factors or a combination thereof can be taken into account in the issue of implementing a specific compensation: risk assessment of impact, costs and probability. A risk assessment is preferably performed based on one or more point(s), such as probability, consequences, costs of damage limitation or even elimination.

One possible compensation could include, for example, monitoring which detects failure of an element of the twin and, in response, transitions to a more robust state in which “nothing bad happens”.

If the disruption causes, for example, subsequent disruptions, then the disruption itself in the system twin, but also its sequences (a disruption cascade) is preferably simulated.

In other words, the system twin is enhanced with data that is generated using a disruption simulation, as a result of which the system twin is expanded by robustness aspects that are relevant to the application scenario (environment).

The quality of a statement about the robustness of a complex system is higher and more comprehensive as a result of this proposal.

The system is preferably a drive system.

Preferably, a drive system comprises an electronic control unit, such as a converter, in particular a frequency converter, in particular the system is formed a control unit, for example, as a converter, in particular as a frequency converter.

DC applications, for example, may be considered as the environment. For example, the environment can thus comprise one or a combination of (large) interconnected intermediate circuits, battery applications, DC switches and fuses.

In one embodiment, the drive system additionally comprises an electric rotary machine, preferably an electric motor, such as an asynchronous motor.

The electronic control unit can be connected to the electric rotary machine in order to supply it with current and voltage with certain adjustable characteristics (amplitude, and/or frequency) and consequently, for example, to reduce or increase its torque to the required level in order to meet the requirements of the application.

Such drive systems can drive, for example, axes of a machine tool or of a robot arm, pumps (hydraulic drive), and/or conveyor belts, for which reason they are often also referred to as drives or drive trains.

A digital twin of a system is basically a virtual representation of the real system, which can preferably be updated based on data from various data sources, such as historical data, and/or measurement data. First, a digital twin can, in particular, be formed from static data (e.g., identification plates, catalog details, manufacturer data sheets and/or characteristic curves) and subsequently be updated, for example, during operation. A digital twin formed from the static data can be used, in particular, in the design phase.

In other words, a digital twin is a replica of a physical object of a physical system in software which, in particular, replicates an input-output behavior and/or the internal function (for example, via a transfer function) and enables internal parameters (for example, switching speed, max. frequency) of the system to be adapted without having to make changes to the real system.

It is expedient if a digital twin can be updated in real time, such as during operation, based on sensor data that supplies the sensors assigned to the system.

The historical data can comprise, for example, operational data, construction drawings, and models, maintenance histories, and other information collected over the life of the drive system.

The digital twin can offer a large number of functions, such as monitoring, simulating and predicting performance and state of the system. It can also serve as a digital model for the optimization of maintenance processes and the improvement of the performance. Furthermore, the digital twin can also help to reduce downtimes and maintenance costs by detecting potential problems early and recommending appropriate measures. It may also improve the efficiency of the system by proposing optimal operating conditions and monitoring performance over time.

Overall, a digital twin of the system offers a powerful possibility of optimizing the performance and efficiency of the drive system and at the same time lowering the maintenance costs. In particular, a digital twin can make it possible to perform fault experiments and/or to improve the physical design without experimenting on the real system being.

In particular, the digital twin of a system in the context of the present Of disclosure is taken to mean a simulation model of the system. Such a simulation model can be present, for example, in the form of a Functional Mock-up Unit (FMU). The simulation model can be constructed in a modular manner, with each module of the simulation model describing a specific domain of the drive system (thermal aspects, and/or electrics).

The FMUs can be linked to one another via Functional Mock-up Interfaces (FMIs). An FMI is a standard interface for the exchange of model-based simulations between different simulation tools and environments. In other words, the FMU is a manifestation of the FMI standard.

The system twin and the environment model can also be formed as modules of the overall model, which can be implemented, for example, as software, and can be linked in this overall model. The link can be configured, for example, via an operator interface of the overall model. The system twin and the environment model do not have to be formed as independently manageable components, such as FMUs. The link therefore is not required to correspond to the FMI standard.

FMI defines a standardized data format for model-based simulations, which can be based, for example, on XML and binary files. It enables an exchange of model components and their connections between different simulation environments and tools. The FMI enables complex systems to be created from various components and models that can be configured in various simulation environments and tools.

In one embodiment, at least one corresponding change in the system is preferably performed based on the changed behavior model. It can be expedient to perform a risk analysis before adopting a suggested change.

In one embodiment, if the expected effect comprises one or more fault(s) within the overall system, then at least one solution is ascertained within the system twin, with the at least one solution at least lessening and preferably partially compensating or offsetting the one or more fault(s).

In another embodiment, the overall model is changed such that it comprises the environment model and the system twin with the changed behavior model, the changed overall model is executed, where the (same) disruption of the system is co-simulated when the changed overall model is executed, and changed simulation results obtained thereby are validated on the overall system.

It can be expedient if, during the validation, a ranking of the change performed on the behavior model of the system twin is implemented.

Preferably, the ranking comprises a weighting with regard to an efficiency of the change or the performed remedial measures and/or the effort of implementing the change on the system and/or the costs of implementing the change on the system.

In a further embodiment, disruptive inputs corresponding to the predefined disruptions are provided in the system twin.

In another embodiment, when analyzing the simulation data, a risk-based evaluation of a situation to be expected due to the expected effect of the at least one disruption on the overall system is performed and, for example, is reported to a user.

This can be implemented based on the safety-relevant parameters and/or the expected state of the overall system or the like.

The evaluation preferably comprises an assessment with regard to danger or criticality of the situation to be expected due to the expected effect of the at least one disruption on the overall system.

In a further embodiment, a simulation of the overall system in an undisrupted state is used when analyzing the simulation data. The real system in the environment is simulated both in the undisrupted state and under the influence of the at least one disruption. Results of the simulation of the system without disruption are compared and analyzed with the results of the simulation of the system under the influence of the disruption.

In a further embodiment, two or more disruptions are co-simulated to simulate the behavior of the overall system under the influence of the two or more disruptions acting on the system and to obtain simulation data.

The disruptions can be different or of the same type or proceed according to the difference or according to the same disruptive mechanisms. That is, it is possible, for example, to simulate two disruptions in which two components malfunction or two different disruptions are injected onto the input signal. These are different disruptive scenarios that can be simulated in the overall model.

In one embodiment, the method comprises
a simulation of the undisrupted overall model,
a simulation of the overall model taking into account one or more disruption(s)—simple or k-times disrupted simulation, where k is the number of simulated disruptions, and where each disruption can be assigned to a specific disruptive mechanism,
a subsequent, preferably risk-based evaluation of the expected effect of the disruption(s),
a proposal of one or more remedial measure(s) which, for example, relate(s) to the behavior model, where the number of remedial measures can be smaller than the number of disruptions,
a simulation of the overall model taking into account the disruption(s) and the remedial measure(s), and
an evaluation of the remedial measure(s), with it being possible, for example for a user, to generate a justification with respect to the remedial measure(s), preferably with an indication of a weighting (according to costs, and/or effort).

When the behavior model is changed, the user is preferably advised that a more robust digital twin now exists, and that corresponding changes to the real drive system are to be followed.

In summary, the disclosed embodiments of the method make it possible, inter alia, to map faults in the object itself and thus to create a system twin that is comprehensively centered in terms of its robustness aspects, i.e., in each of its components.

Based on these findings, in addition to design decisions (dimensioning of the objects, safety factors), monitoring and fault control algorithms may also be developed, or measures (e.g., redundancy) may be derived.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention will be explained in more detail below on the basis of exemplary embodiments, which:

FIG. 1 shows a facility 100 for developing a digital twin in accordance with the invention; and

FIG. 2 is a flowchart of a computer-implemented method for optimizing a robustness of a digital twin of a system in accordance with the invention.

### DETAILED DESCRIPTION OF THE EXEMPLARY EMBODIMENTS

The reference numerals used in the figures serve exclusively for improving readability and are not to be interpreted as limiting. The same reference numerals in different figures denote substantially identical elements or items.

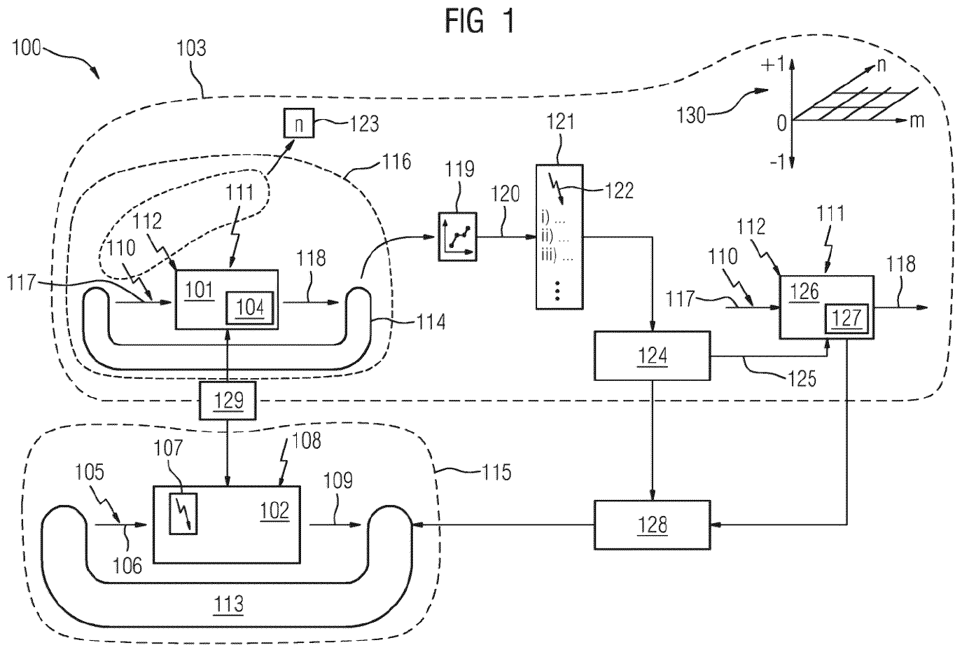

FIG. 1 shows a facility 100 for optimizing and developing a digital twin 101 of a (real) drive 102 (a system drive twin) and illustrates a computer-assisted method in order to optimize the drive twin 101 and to develop it based on the optimization that has occurred.

In an advantageous embodiment, the drive twin 101 and preferably each of its components and/or models (mechanical, thermal, and/or electrical model), which can be formed as modules of a software program, can be configured with regard to their degree of detail.

Such a facility 100 and such a method can be used, for example, in the context of a configuration phase or a configuration of the drive 102, in which the robustness of the drive 102 or its project engineering and the object contained therein is examined. The aim of such an examination can be, for example, estimating the risk and also the associated costs and ascertaining load limits and/or breaking points of components of the drive 102.

The facility 100 comprises a computing system 103 that can be configured, for example, as one or more, for example, distributed computing unit(s) or platform(s) (not shown here). For example, the computing system 103 can be configured as a Cloud. In principle, such a computing system comprises means operatively coupled to one another for implementing the necessary steps of the method represented here, such as databases, memories, processors, and/or data lines.

The drive twin 101 is stored in the facility 100. The drive twin 101 comprises a behavior model 104 that describes both an undisrupted behavior and a behavior of the drive 102 that is to be expected under the influence of one or more predefined disruption(s) that occur with a non-negligible probability during operation of the drive 102.

A disruption can occur, for example, as a disruption 105 at the input signal 106 and/or as an internal disruption 107 and/or as an external disruption 108.

The disruption is defined in this respect because it is preferably directly measurable. In other words, basically known disruptive influences are considered in the context of the present disclosure.

The internal disruptions 107 comprise, for example, faults that can occur in a real component of the drive 102 (short circuit, shaft break, soldering point problems, failing semiconductors, which impair the input-output transmission function and are not visible from the outside).

External stimuli of the drive 102 can also be faulty during operation (for example, target value and/or ambient temperature is outside the valid range; security breaches if, for example, the input signal has been compromised, has occurred) and the response thereto can be examined.

The disruptions 105 at the input signal 106 can, for example, comprise noise. Disruptions of this kind are visible at the output/output signal 109.

Alternatively or additionally, disruptions can also comprise disruptions on a side channel (irradiation, vibration on the housing).

In other words, the drive twin 101 enables one of the aforementioned disruptions 105, 107, 108 or a combination thereof to be simulated. This simulation can consist, for example, because one or more disruptive function(s) 110, 111 is/are injected, or a component of the drive twin 101 (which corresponds to a real component of the drive 102) is deleted or deactivated 112 because this corresponds to a failure of the real component. This can be, for example, partial or complete malfunctions in a motor, in a transmitter, in the sensor system, in the power electronics. Specifically, the behavior model 104 can simulate, for example, an Insulated-Gate Bipolar Transistor (IGBT) malfunction, which occurs with an associated probability as a function of load cycles (“cycle counter”).

In summary, three disruptive mechanisms or a combination thereof can be simulated in the drive twin 101:
disruption on an input (also results from a disruption of the environment model, also noise);
disruption as its own “non-functional” input (for example, radiation, temperature);
disruption as its own logical input (component malfunctions).

It can therefore be provided that the entire drive twin 101 and/or one or more of its component(s) is/are provided with malfunction probabilities. The malfunction probabilities are usually their own static parameters and not a time-dependent input.

With the aid of the malfunction probabilities, it is possible, for example, to achieve an EMEA-equivalent result (for example, evaluation of the vulnerabilities and criticality of the components of a system).

In addition, it can be provided that disruptive variable transmission functions are additionally mapped in the drive twin.

In addition, a model of an environment 113 (an environment model 114) in which the drive 102 is applied or used, is stored in the computing system 103. In other words, the environment 113 corresponds to the application scenario of the drive 102.

The drive 102 is therefore configured to interact with the environment such that the environment 113 supplies at least one, preferably all, input signals 106 to the drive 102 and receives at least one, preferably all, output signals 109 from the drive 102. Together with the environment 113, the drive 102 thus forms an overall system 115.

The environment 113 of the drive 102 can be configured differently. For example, the environment 113 can be formed as a large, interconnected DC network, in which, for example, a DC link can short-circuit or a fuse can short.

In addition, the environment 113 can be configured as a superimposed control of the drive 102 and comprise one or more programmable logic control(s) (PLC). In the manner described below, for example, the control design within the drive 102 can be improved with regard to its robustness with the aid of the drive twin 101.

The drive twin 101 can be formed, for example, as an FMU.

Disruptive inputs can be provided in the drive twin 101 for the disruption simulation 110, 111, 112. Each disruptive input corresponds to one of the disruptions 110, 111, 112. In other words, interfaces can be provided in the drive twin 101 in order to trigger potential fault events contained in the drive twin 101. Parameters corresponding to the disruptive inputs/interfaces and preferably also their tolerances can be set via disruptive inputs/interfaces.

If the drive twin 101 comprises a plurality of models, each model can comprise its own interfaces. In the case of a coupling/aggregation of a plurality of models to form a larger drive twin 101, the external interfaces (of the models) are automatically simulated for internal interfaces, via the propagation of the corresponding disruption 105, 107, 108 and/or of the subsequent faults. The type of external interface defines from the outset which disruption can and should be simulated or which faults can and should be injected to assist the user in which scenarios are to be expediently taken into account in the fault simulation.

To assist the user, the drive twin 101 can furthermore have an Application Programming Interface (API).

For example, the API can be configured such that it can include surrounding systems in the calculation of the malfunction probability (and its intermediate results).

In an expedient embodiment, the drive twin 101 is equipped with an algorithm that enables the ascertainment of the malfunction probability and all intermediate results associated therewith (e.g., component load, and/or lifetime consumption).

The drive twin 101 and the environment model 114 are linked, for example, in a simulation tool encompassed by the computing system 103 to form an overall model 116, i.e., a model of the overall system 115.

The overall model 116 is now executed (by the computing system 103) to simulate the behavior of the overall system 115. The computing system 103 can also be configured such that the overall model 116 is divided or also calculated in parallel (see EMI Spec: Distributed co-simulation infrastructure). Simulation input signals 117 are specified and simulation output signals 118 are considered and analyzed.

Furthermore, at least one disruption 105, 107, 108 of the drive 102 is co-simulated during the execution of the overall model 116 to simulate the behavior of the overall system 115 under the influence of the disruption 105, 107, 108 acting on the drive 102 and to obtain simulation data. In other words, disruptive behavior of the real overall system 115 is examined.

In order to investigate reaction of the real overall system 115 to one or more predefined disruption(s) 105, 107, 108, in the case of the drive twin 101, the simulation input signals 117 can be acted upon by a disruptive function 110, the external disruption functions 111 can be triggered, the internal disruptive functions 112 can be triggered, or any combination of these disruption simulations can be activated, which results in an extensive examination of the possible disruptions.

One or more of the aforementioned disruptive input(s) of the drive twin 101 can be used for this purpose.

Simulation data 119 is generated in the course of the simulation. This data 119 is then analyzed 120 to ascertain an expected effect 121 of the disruption 105, 107, 108 on the overall system 115.

Detailed analysis data can be derived from the simulation data 119 on the effective path 121 of the simulated disruption 122. In other words, the effect 121 along the path along which the disruption propagates is ascertained and can comprise individual faults in components as well as subsequent faults in other components or in the drive twin 101. In other words, in the case of simulation, a fault cascade i), ii), ii) that comprises a plurality of disruptions and subsequent disruptions can be examined. The analysis data for the effective path 121 can enable an estimation of fault interactions, subsequent faults, or fault cascades.

Thus, with the aid of the (same) drive twin 101, a fault search in the field can be supported. Faults from the field (due to disruptions 105, 107, 108) are readjusted by the drive twin 101 (by injecting the simulated disruptions 110, 111, 112). It is possible to ascertain whether the field experience coincides with the simulation behavior of the drive twin 101. It is possible, for example, to propose an assignment of the faults in database with probabilities and/or exchange of components with the aid of AI.

The fault states and operating mechanisms to be included can be identified, for example, based on one or more of standards, empirical values, over-dimensioning, safety factors and FMEA, which can be present in a data memory of the computing system 103.

The drive twin 101 can have one or more disruptive input(s). Accordingly, fault states in the drive twin 101 (and in its individual components) can be actuated separately.

When analyzing the simulation data 119, an assessment with regard to danger or criticality of a situation, which is to be expected by the expected effect 121 of the disruption 105, 107, 108 on the overall system 115, can be performed. This can be implemented based on the safety-relevant parameters and/or the expected state of the overall system 115 or the like. The result of the assessment can be reported to a user, for example.

In other words, the simulation data 119 is examined with regard to dangerous faults, dangerous scenarios and also measures to avoid such scenarios.

For example, a simulation of the overall system 115 in an undisrupted state can be used when analyzing the simulation data 119. The drive 102 in the environment 113 is simulated both in the undisrupted state and under the influence of the disruption 105, 107, 108. The results of the simulation of the drive 102 without disruption are compared and analyzed with the results of the simulation of the drive under the influence of the disruption 105, 107, 108.

This can be performed, for example, within the context of post-processing and/or a feature extraction of the simulation data. It is possible to check, for example, whether an output of the driving twin 101 has come to a stop and whether, for example, a critical fault has been caused thereby.

This danger or criticality of the disruptive injection can be ascertained via a plurality of passes of the simulation.

Different disruptive scenarios 123 can be simulated in each pass. A specific simulated disruption 110, 111, 112 or a specific combination of the simulated disruptions 110, 111, 112 is referred to as a disruptive scenario.

For example, in the case of three described disruptive mechanisms, there can be n disruptive scenarios 123, where n is dependent on ni, where ni is the number of possible disruptions of the i^{th} mechanism, for example, the components that can malfunction. If two components malfunction, this is a 2-fold disruption of the “malfunction” disruptive mechanism, etc.

Each simulated disruption 122 (selected from n disruptive scenarios 123) can cause a fault state condition. In this regard, a fault injection can be spoken of when a disruption 110, 111, 112 is injected.

The drive twin 101 can have different levels of detail with respect to fault states so that not all interfaces/parameters have to be served from the outside. The selected model in the drive twin 101 can be communicated to the user, for example, in the API, which may be provided as an alternative to FMI.

For example, it is thus possible for other data to be available in the design process than in the operating phase (for example, current or voltage harmonics above half the sampling clock of the current or voltage sensors during operation may not be identified without a separate measuring system (Shannon Theorem), but can be in the design phase). If necessary, parts of the drive twin 101 may be used to infer fault state-relevant variables (virtual sensor for disruptive variable transmission function).

It is possible for selected fault states of sub-components of one of the drive twin 101 to mutually influence one another and, even without the targeted selection from the outside, allow a detailing of a subsystem in order to be able to ascertain subsequent faults.

The drive twin 101 is preferably configured such that, depending on the issue, the degree of detail of the partial components can be selected automatically, or such that the manually specified degree of detail of a partial component influences its adjacent components, in order to thereby ensure a consistency with regard to the accuracy of the mapping of a fault.

When “trying out” various disruptive scenarios 123, knowledge about active paths 121 of the disruptions and thus about the possible disruptive mechanisms is generated and stored, for example, in a memory 124 provided for this purpose.

If a disruptive scenario 123 leads to a fault, it is a fault scenario

Based on the ascertained expected effect 121 of the at least one disruption 105, 107, 108 on the overall system 115, or on the generated knowledge about the disruptive mechanisms, one or more measure(s) or modifications is/are ascertained, which can be performed within the drive twin 101 and enable the expected effect 121 to be at least partially compensated.

For example, in the case of an internal fault 107 that comprises the failure of an internal component of the drive 102 and that is simulated by deletion or deactivation at the run time 112 of a corresponding component in the drive twin 101, the modification can provide a monitoring mechanism that detects the failure of the component and transfers the drive twin 101 into a more robust state in which the effect 121 is at least partially compensated, for example no output of the drive twin 101 comes to a stop.

In an advantageous embodiment, if the expected effect 121 comprises one or more fault(s) within the overall model 116, then the computing system 103 ascertains a solution within the drive twin 101 based on the simulation data 119 and, in particular, based on the detailed analysis data 121 on the effective path, with the one solution transferring the overall model 116 (or its simulation) into a more secure state by, for example, at least partially compensating for the one or more fault(s), in particular such that one or more subsequent fault(s) is/are avoided or their danger or criticality is reduced.

Accordingly, the behavior model 104 of the driving twin 101 can be adapted 125 by such a measure or with such a modification.

In other words, the modification can be aimed at reducing consequences of a simulated disruption 110, 111, 112, or a simulated disruption scenario 123, and thus avoiding subsequent disruptions.

A solution or solution scenario can relate to one or more of the disruption scenario(s) 123.

For example, m solution scenarios can be ascertained for n disruptive scenarios and m<n. The solution scenarios can comprise one or a combination of the following measures: compensation of the expected effect, transfer to a safe state, emergency shutdown, and/or adjustment of the maintenance intervals.

These m solution alternatives can then be tested, with it being possible to introduce a scoring 130 in the verification of the solution alternatives if the corresponding solution has a good enough effect. Evaluation factors such as cost-dependent, greater safety, and/or implementability can be considered.

In the case of scoring 130, a distinctive number that quantify the robustness can be assigned, for example, to a solution scenario. This can be done, for example, based on a measure of distance from the undisrupted signal and characterize suppression of the disruption, etc.

A single (optimum) solution is preferably transferred or validated into the real system.

In particular, the measure can be that the danger of the situation arising in the selected disruption scenario is reduced.

The modification can be transmitted into the drive twin 101. This results in an improved drive twin 126 with a changed behavior model 127 with regard to its robustness connected to the known aforementioned disruptive scenarios.

The modified drive twin 126 is more robust than the drive twin 101.

The modified drive twin 126 can be stored in the memory 124, for example.

In an expedient embodiment of the facility 100, the computing system 103 proposes 128 a change of the drive 102 based on the modified drive twin 126 and, in particular, the changed behavior model 127.

The ascertained measure can then be verified on the overall system 115. For this purpose, the overall model 116 is changed because it comprises the (old) environment model 114 and the modified drive twin 126. The computing system 103 then executes the changed overall model, the (same) disruption of the drive 102 is co-simulated that has resulted in the aforementioned modification measure of the drive twin 101 when executing the changed overall model. The simulation results obtained are validated 129 on the overall system.

The facility 100 described above can thus also be used for testing the drive 102 in the environment 113.

The knowledge 124, obtained within the context of the simulation described above, about various disruptive mechanisms and solutions derived from this knowledge 124 can be used to modify the drive 102.

This is useful, in particular, within the context of a design of the drive 102. For this purpose, the aforementioned simulation tool can be a component of a design tool in the computing system 103 or can be configured as a design tool.

It should be understood that the simulation tool, design tool can interact conventionally with the memory 124 and with other components of the computing system 103, which are not shown here for the sake of simplicity.

In summary, the disclosed embodiments of the methods and systems are aimed, in particular, at ascertaining constructive and/or control-engineering (for example, limiting rise times, controller factors, and/or limiters) and/or monitoring-engineering interventions in the event of failure of the drive system 102 or, in other words, at fault analysis and fault control in the drive system 102. Reactions are defined that are realized in the event of failure of the drive system 102 in order to avoid the fatal faults, with the advantage that these reactions can first be simulated in the drive twin 101. Examples of this are when a sensor signal is missing, then a support brake is actuated, adjustment of a service interval, such as in the event of early failure.

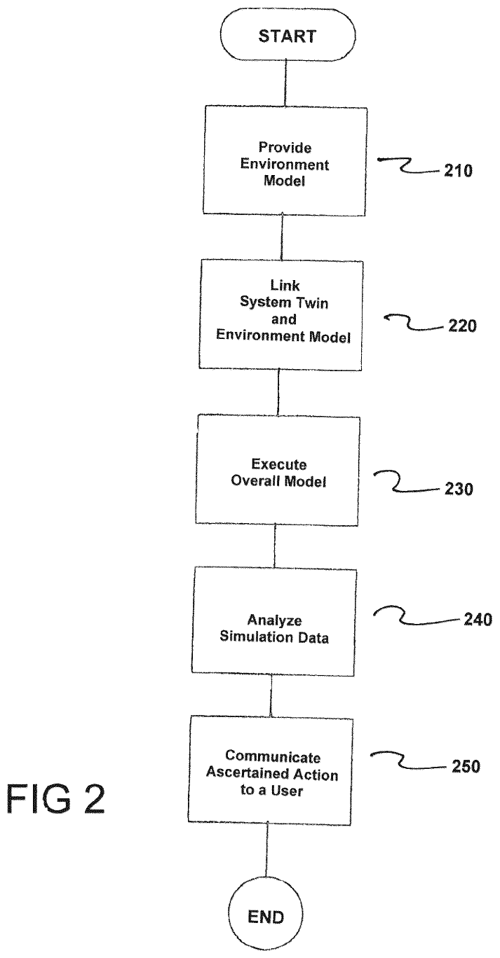

FIG. 2 is a flowchart of the computer-implemented method for optimizing the robustness of a digital twin of a system 102 comprising a system drive twin 101, where the system drive twin 101 comprises a behavior model 104 that describes an undisrupted behavior and a behavior of the system 102 that is to be expected under influence of at least one predefined disruption 105, 107, 108.

The method comprises providing a model of an environment 113 representing an environment model 114, as indicated in step 210. In accordance with the inventive method, the system 102 is configured to interact with the environment 113 such that the environment 113 supplies at least one input signal 106 to the system 102 and receives at least one output signal 109 from the system 102, and the system 102 together with the environment 113 jointly form an overall system 115.

Next, the system twin 101 and the environment model 114 are linked to form an overall model 116 comprising a model of the overall system, as indicated in step 220.

Next, the overall model 116 is executed at least twice to obtain simulation data 119, as indicated in step 230. In accordance with the inventive method, during the first execution, the overall model 116 is utilized in an undisrupted state and, in cases of the second execution of the overall model 116, the at least one predefined disruption 105, 107, 108 of the system 102 is co-simulated to simulate the behavior of the overall system 115 under influence of the at least one predefined disruption 105, 107, 108 acting on the system 102.

Next, simulation data 119 is analyzed to ascertain an expected effect 121 of the at least one disruption 105, 107, 108 on the overall system 115 from a comparison of data ascertained during the first execution of the overall model 116 with data ascertained during the second execution of the overall model 116, as indicated in step 240.

Next, the ascertained at least one action is communicated to a user depending on the expected effect 121, as indicated in step 250.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-14. (canceled)

15. A computer-implemented method for optimizing a robustness of a digital twin of a system comprising a system drive twin, the system drive twin comprising a behavior model which describes an undisrupted behavior and a behavior of the system which is to be expected under influence of at least one predefined disruption, the method comprising:
providing a model of an environment representing an environment model, the system being configured to interact with the environment such that the environment supplies at least one input signal to the system and receives at least one output signal from the system, and the system together with the environment jointly form an overall system;
linking the system twin and the environment model to form an overall model comprising a model of the overall system;
executing the overall model at least twice to obtain simulation data, during a first execution, the overall model being utilized in an undisrupted state and, in cases of a second execution of the overall model, the at least one predefined disruption of the system being co-simulated to simulate a behavior of the overall system under influence of the at least one predefined disruption acting on the system;
analyzing simulation data to ascertain an expected effect of the at least one disruption on the overall system from a comparison of data ascertained during the first execution of the overall model with data ascertained during the second execution of the overall model; and
communicating the ascertained at least one action to a user depending on the expected effect.

16. The method as claimed in claim 15, further comprising:
determining a situation to be expected due to the expected effect of the at least one disruption on the overall system when ascertaining the at least one action; and
performing a risk-based assessment of the situation when ascertaining the at least one action.

17. The method as claimed in claim 15, wherein the at least one action is evaluated with regard to predefinable parameters.

18. The method as claimed in claim 15, wherein the at least one action is evaluated with regard to predefinable parameters.

19. The method as claimed in claim 15, wherein at least two disruptions of the system are co-simulated to simulate the behavior of the overall system under the influence of the at least two disruptions acting on the system and to obtain simulation data for a plurality of disruptive scenarios.

20. The method as claimed in claim 19, wherein the expected effect is ascertained for each disruption scenario; and wherein at least one action for at least one expected effect is ascertained and communicated to the user.

21. The method as claimed in claim 15, wherein the action comprises changing the behavior model of the system twin to reduce the expected effect.

22. The method as claimed in claim 21, wherein at least one corresponding change in the system is proposed based on the changed behavior model.

23. The method as claimed in claim 21, further comprising:
changing the overall model such that the overall model comprises the environmental model and the system twin with the changed behavior model; and
executing the changed overall model;
wherein disruption of the system is co-simulated such that obtained, changed simulation results are validated on the overall system when executing the changed overall model.

24. The method as claimed in claim 22, further comprising:
changing the overall model such that the overall model comprises the environmental model and the system twin with the changed behavior model; and
executing the changed overall model;
wherein disruption of the system is co-simulated such that obtained, changed simulation results are validated on the overall system when executing the changed overall model.

25. The method as claimed in claim 23, wherein a ranking of the change performed on the behavior model of the system twin is performed during the validation.

26. The method as claimed in claim 25, wherein the ranking comprises at least one of (i) a weighting with regard to an efficiency of the change, (ii) a required effort to implement the change on the system and (iii) a cost of implementing the change on the system.

27. The method as claimed in claim 15, wherein disruptive inputs corresponding to the predefined disruptions are provided in the system twin.

28. A method for designing at least one drive system, wherein the digital twin of the drive system comprising the system drive twin is optimized in accordance with the method as claimed in claim 15 and the drive system is configured in accordance with the optimized driving twin.

29. A facility for optimizing robustness of a digital twin of a system comprising a system digital twin, wherein the facility comprises the system, an environment of the system, and a computing system, wherein the computing system is configured to execute a method as claimed in one of claim 15.

30. A computer program product for the facility as claimed in claim 13, wherein the computer program product comprises instructions which, when executed by a computing system of the facility, cause the facility to:
provide a model of an environment representing an environment model, the computing system being configured to interact with the environment such that the environment supplies at least one input signal to the computing system and receives at least one output signal from the computing system, and the computing system together with the environment jointly form an overall system;
link a system twin and the environment model to form an overall model comprising a model of the overall system;
execute the overall model at least twice to obtain simulation data, during a first execution, the overall model being utilized in an undisrupted state and, in cases of a second execution of the overall model, the at least one predefined disruption of the computing system being co-simulated to simulate a behavior of the overall system under influence of the at least one predefined disruption acting on the computing system;
analyze simulation data to ascertain an expected effect of the at least one disruption on the overall system from a comparison of data ascertained during the first execution of the overall model with data ascertained during the second execution of the overall model; and
communicate the ascertained at least one action to a user depending on the expected effect.
